(19) United States
(12) Patent Application Publication
(10) Pub. No.: US 2014/0048859 A1
(43) Pub. Date: Feb. 20, 2014

(54) SEMICONDUCTOR DEVICE AND METHOD OF MANUFACTURING THEREOF

(71) Applicant: Elpida Memory, Inc., Tokyo (JP)

(72) Inventor: Yoko NAKANO, Tokyo (JP)

(21) Appl. No.: 13/933,802

(22) Filed: Jul. 2, 2013

(30) Foreign Application Priority Data
Aug. 17, 2012 (JP) 2012-181078

(51) Int. Cl. H01L 29/49

(52) U.S. Cl. CPC H01L 29/4975
USPC 257/296; 257/411; 257/330

(57) ABSTRACT

Disclosed is a semiconductor device including: a titanium nitride film formed over a semiconductor substrate and a tungsten film formed over the titanium nitride film. The titanium nitride film contains carbon and the tungsten film contains boron. A tungsten hexafluoride gas and a diborane gas are used in formation of the tungsten film.

This application is based upon and claims the benefit of priority from Japanese patent application No. 2012-181078, filed on Aug. 17, 2012, the disclosure of which is incorporated herein in its entirety by reference.

### BACKGROUND OF THE INVENTION

1. Field of the Invention

This invention relates to a semiconductor device and a manufacturing method therefor.

2. Description of the Related Art

A tungsten (W) wiring is often used as a wiring, a contact plug, a via plug, or the like of a transistor formed on a substrate. A barrier film is provided below the tungsten wiring, and the like, and titanium nitride (TiN) is often used as a material thereof.

With regard to formation of the barrier film, Japanese Unexamined Patent Application Publication Nos. 2007-194468, Hei 8-172060, and Hei 2-133964 and Japanese Patent Translation Publication No. Sho 62-500060 are known. Specifically, Japanese Unexamined Patent Application Publication No. 2007-194468 discloses a method involving growing tungsten on a titanium nitride (TiN) film using a diborane (B₂H₆) gas.

Japanese Unexamined Patent Application Publication No. Hei 8-172060 discloses a method involving forming an inert substance by adding boron or carbon to a barrier film and causing the added boron or carbon to react with an unreacted substance in a metal film.

Japanese Unexamined Patent Application Publication No. Hei 2-133964 discloses addition of 1 to 10 at % carbon to a titanium nitride film for the purpose of alleviating stress on the titanium nitride film.

Japanese Patent Translation Publication No. Sho 62-500060 discloses a barrier layer formed of titanium carbonitride as a barrier layer for preventing interdiffusion between aluminum (Al) and silicon (Si).

By the way, when tungsten (W) is grown by reducing tungsten hexafluoride (WF₆) using diborane (B₂H₆), the grain boundaries of tungsten can be enlarged to lower the resistance. When such a method is used to grow tungsten and form a wiring, boron (B) is contained in tungsten. In this case, there is a problem that, when boron contained in tungsten passes through the titanium nitride (TiN) layer as the barrier layer to diffuse in a silicon (Si) substrate, instability of operation and degradation of characteristics of the transistor are caused.

Note that, Japanese Unexamined Patent Application Publication Nos. 2007-194468, Hei 8-172060, and Hei 2-133964 and Japanese Patent Translation Publication No. Sho 62-500060 do not disclose the fact that boron contained in tungsten passes through the titanium nitride layer and diffuses in the silicon substrate to cause instability of operation and degradation of characteristics of the transistor. Further, no description or even suggestion is found which can be a motivation to combine the above-mentioned Japanese Unexamined Patent Application Publication Nos. 2007-194468, Hei 8-172060, and Hei 2-133964 and Japanese Patent Translation Publication No. Sho 62-500060.

### SUMMARY

In one embodiment of the invention, there is provided a semiconductor device, comprises: a titanium nitride film comprising carbon, the titanium nitride film being formed over a semiconductor substrate; and a tungsten film comprising boron, the tungsten film being formed over the titanium nitride film.

In another embodiment, a semiconductor device comprises: a gate groove provided in a semiconductor substrate; an insulating film provided so as to cover a surface of the gate groove; a titanium nitride film comprising carbon, the titanium nitride film being provided over the insulating film; and a tungsten film provided over the titanium nitride film.

In still another embodiment, a semiconductor device comprises: an element isolation region provided in a semiconductor substrate and defining an active region; a groove provided in a surface layer of the semiconductor substrate, the groove extending in a first direction intersecting with the element isolation region and the active region;

a gate insulating film covering a surface of the groove for a gate electrode;
a buried gate electrode formed so as to be buried at a bottom portion of the groove, the buried gate electrode being formed as a word line; and a pair of diffusion layers that is provided on an upper surface of the semiconductor substrate, and is located on both sides of the groove for a gate electrode in the active region, wherein the buried gate electrode comprises a titanium nitride film and a tungsten film, the titanium nitride film being provided on the gate insulating film and comprising carbon, the tungsten film being provided on the titanium nitride film.

According to a further embodiment of this invention, there is provided a method of manufacturing a semiconductor device comprising: forming over a semiconductor substrate, a titanium nitride film containing carbon; and forming a tungsten film on the titanium nitride film using a tungsten hexafluoride gas and a diborane gas.

In accordance with the embodiment, the tungsten film has enlarged grain boundaries and a low resistance and the titanium nitride film comprises one with inhibited columnar crystallinity. Thus, diffusion of boron (B) from the tungsten film into the semiconductor substrate can be prevented.

### BRIEF DESCRIPTION OF THE DRAWINGS

In the accompanying drawings:

FIG. 1 is a plan view of a semiconductor device according to an embodiment;

FIG. 2A illustrates memory cells of the semiconductor device according to the embodiment, and is a sectional view taken along the line A-A of FIG. 1;

FIG. 2B illustrates the memory cells of the semiconductor device according to the one embodiment, and is a sectional view taken along the line B-B of FIG. 1;

FIG. 2C is an enlarged sectional view of a portion surrounded by a two-dot chain line of FIG. 2A;

FIG. 3A is a sectional view taken along the line A-A of FIG. 1 and illustrating a step in a method of manufacturing the semiconductor device according to the embodiment;

FIG. 3B is a sectional view taken along the line B-B of FIG. 1 and illustrating the step in the method of manufacturing the semiconductor device according to the embodiment;

FIG. 4A is a sectional view taken along the line A-A of FIG. 1 and illustrating a step in the method of manufacturing the semiconductor device according to the embodiment;

FIG. 4B is a sectional view taken along the line B-B of FIG. 1 and illustrating the step in the method of manufacturing the semiconductor device according to the embodiment;

FIG. 5A is a sectional view taken along the line A-A of FIG. 1 and illustrating a step in the method of manufacturing the semiconductor device according to the embodiment t;

FIG. 5B is a sectional view taken along the line B-B of FIG. 1 and illustrating the step in the method of manufacturing the semiconductor device according to the embodiment;

FIG. 6A is a sectional view taken along the line A-A of FIG. 1 and illustrating a step in the method of manufacturing the semiconductor device according to the embodiment;

FIG. 6B is a sectional view taken along the line B-B of FIG. 1 and illustrating the step in the method of manufacturing the semiconductor device according to the embodiment;

FIG. 7A is a sectional view taken along the line A-A of FIG. 1 and illustrating a step in the method of manufacturing the semiconductor device according to the embodiment;

FIG. 7B is a sectional view taken along the line B-B of FIG. 1 and illustrating the step in the method of manufacturing the semiconductor device according to the embodiment;

FIG. 8A is a sectional view taken along the line A-A of FIG. 1 and illustrating a step in the method of manufacturing the semiconductor device according to the embodiment;

FIG. 8B is a sectional view taken along the line B-B of FIG. 1 and illustrating the step in the method of manufacturing the semiconductor device according to the embodiment;

FIG. 9A is a sectional view taken along the line A-A of FIG. 1 and illustrating a step in the method of manufacturing the semiconductor device according to the embodiment;

FIG. 9B is a sectional view taken along the line B-B of FIG. 1 and illustrating the step in the method of manufacturing the semiconductor device according to the embodiment;

FIG. 10A is a sectional view taken along the line A-A of FIG. 1 and illustrating a step in the method of manufacturing the semiconductor device according to the embodiment;

FIG. 10B is a sectional view taken along the line B-B of FIG. 1 and illustrating the step in the method of manufacturing the semiconductor device according to the embodiment;

FIG. 11A is a sectional view taken along the line A-A of FIG. 1 and illustrating a step in the method of manufacturing the semiconductor device according to the one embodiment;

FIG. 11B is a sectional view taken along the line B-B of FIG. 1 and illustrating the step in the method of manufacturing the semiconductor device according to the embodiment;

FIG. 12A is a sectional view taken along the line A-A of FIG. and 1 illustrating a step in the method of manufacturing the semiconductor device according to the embodiment;

FIG. 12B is a sectional view taken along the line B-B of FIG. 1 and illustrating the step in the method of manufacturing the semiconductor device according to the embodiment;

FIG. 13A is a sectional view taken along the line A-A of FIG. 1 and illustrating a step in the method of manufacturing the semiconductor device according to the embodiment;

FIG. 13B is a sectional view taken along the line B-B of FIG. 1 and illustrating the step in the method of manufacturing the semiconductor device according to the embodiment;

FIG. 14A is a sectional view taken along the line A-A of FIG. 1 and illustrating a step in the method of manufacturing the semiconductor device according to the embodiment;

FIG. 14B is a sectional view taken along the line B-B of FIG. 1 and illustrating the step in the method of manufacturing the semiconductor device according to the embodiment;

FIG. 15A is a sectional view taken along the line A-A of FIG. 1 and illustrating a step in the method of manufacturing the semiconductor device according to the embodiment;

FIG. 15B is a sectional view taken along the line B-B of FIG. 1 and illustrating the step in the method of manufacturing the semiconductor device according to the embodiment;

FIG. 16A is a sectional view taken along the line A-A of FIG. 1 and illustrating a step in the method of manufacturing the semiconductor device according to the embodiment;

FIG. 16B is a sectional view taken along the line B-B of FIG. 1 and illustrating the step in the method of manufacturing the semiconductor device according to the embodiment;

FIG. 17A is a sectional view taken along the line A-A of FIG. 1 and illustrating a step in the method of manufacturing the semiconductor device according to the embodiment;

FIG. 17B is a sectional view taken along the line B-B of FIG. 1 and illustrating the step in the method of manufacturing the semiconductor device according to the embodiment;

FIG. 18A is a sectional view taken along the line A-A of FIG. 1 and illustrating a step in the method of manufacturing the semiconductor device according to the embodiment;

FIG. 18B is a sectional view taken along the line B-B of FIG. 1 and illustrating the step in the method of manufacturing the semiconductor device according to the embodiment;

FIG. 19A is a sectional view taken along the line A-A of FIG. 1 and illustrating a step in the method of manufacturing the semiconductor device according to the embodiment;

FIG. 19B is a sectional view taken along the line B-B of FIG. 1 and illustrating the step in the method of manufacturing the semiconductor device according to the embodiment;

FIG. 20A is a sectional view taken along the line A-A of FIG. 1 and illustrating a step in the method of manufacturing the semiconductor device according to the embodiment;

FIG. 20B is a sectional view taken along the line B-B of FIG. 1 and illustrating the step in the method of manufacturing the semiconductor device according to the embodiment;

FIG. 21A is a sectional view taken along the line A-A of FIG. 1 and illustrating a step in the method of manufacturing the semiconductor device according to the embodiment;

FIG. 21B is a sectional view taken along the line B-B of FIG. 1 and illustrating the step in the method of manufacturing the semiconductor device according to the embodiment;

FIG. 22A is a sectional view taken along the line A-A of FIG. 1 and illustrating a step in the method of manufacturing the semiconductor device according to the embodiment;

FIG. 22B is a sectional view taken along the line B-B of FIG. 1 and illustrating the step in the method of manufacturing the semiconductor device according to the embodiment;

FIG. 23A is a sectional view taken along the line A-A of FIG. 1 and illustrating a step in the method of manufacturing the semiconductor device according to the embodiment;

FIG. 23B is a sectional view taken along the line B-B of FIG. 1 and illustrating the step in the method of manufacturing the semiconductor device according to the embodiment;

FIG. 24A is a sectional view taken along the line A-A of FIG. 1 and illustrating a step in the method of manufacturing the semiconductor device according to the embodiment;

FIG. 24B is a sectional view taken along the line B-B of FIG. 1 and illustrating the step in the method of manufacturing the semiconductor device according to the embodiment;

FIG. 25A is a sectional view taken along the line A-A of FIG. 1 and illustrating a step in the method of manufacturing the semiconductor device according to the embodiment;

FIG. 25B is a sectional view taken along the line B-B of FIG. 1 and illustrating the step in the method of manufacturing the semiconductor device according to the embodiment;

FIG. 26A is a sectional view taken along the line A-A of FIG. 1 and illustrating a step in the method of manufacturing the semiconductor device according to the embodiment;

FIG. 26B is a sectional view taken along the line B-B of FIG. 1 and illustrating the step in the method of manufacturing the semiconductor device according to the embodiment;

FIG. 27A is a sectional view taken along the line A-A of FIG. 1 and illustrating a step in the method of manufacturing the semiconductor device according to the embodiment;

FIG. 27B is a sectional view taken along the line B-B of FIG. 1 illustrating the and step in the method of manufacturing the semiconductor device according to the embodiment;

FIG. 28 is a graph showing the relationship between the manufacturing method and thickness of a titanium nitride film and the number of boron atoms per unit area which have reached a silicon substrate; and

FIG. 29 is a graph showing the relationship between the thickness and the electrical resistivity of each of tungsten films formed by using two kinds of material gases, respectively.

### DETAILED DESCRIPTION OF EXEMPLARY EMBODIMENTS

A semiconductor device according to one embodiment and a manufacturing method therefor are described in detail in the following with reference to the attached drawings. In this embodiment, a dynamic random access memory (DRAM) is described as an example of the semiconductor device. Note that, the drawings which are referred to in the following description may be partly enlarged for the sake of convenience and easy understanding of characteristic features of this invention, and the components are not necessarily drawn to scale. Further, materials, dimensions, and the like in the following description are only exemplary, and this invention is not necessarily limited thereto and appropriate modifications are possible within the gist of this invention.

First, the structure of the DRAM (semiconductor device) according to the embodiment is described.

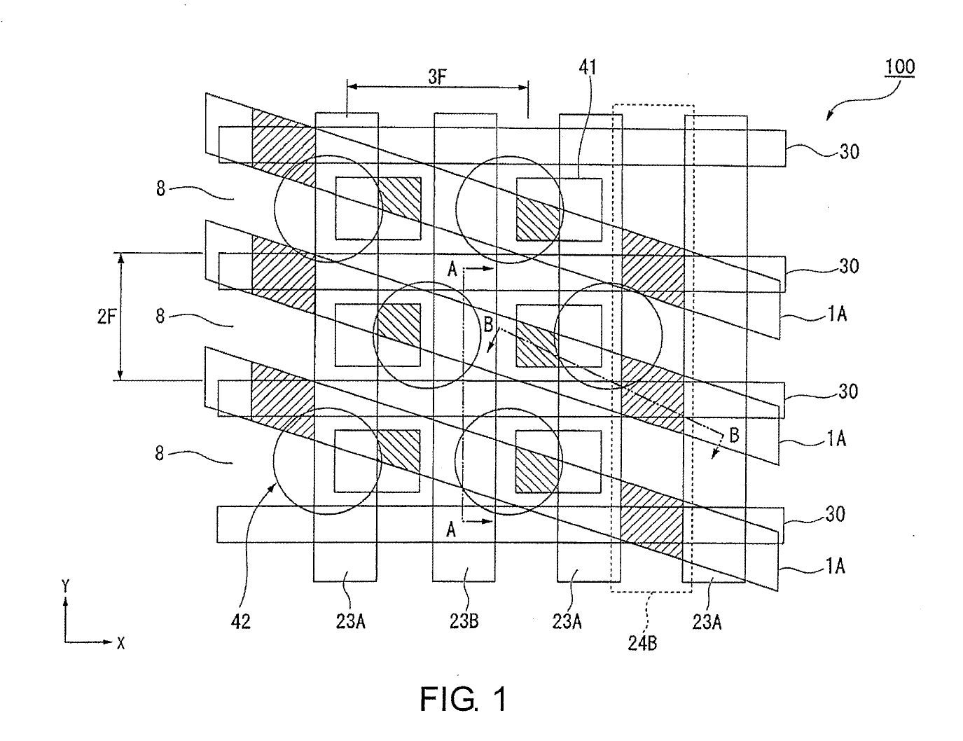

FIG. 1 is a plan view illustrating an exemplary structure of a DRAM 100 according to the embodiment. In FIG. 1, for the sake of clarifying the arrangement of components, capacitors located on capacitor contact pads and upper metal wirings located on the capacitors are omitted.

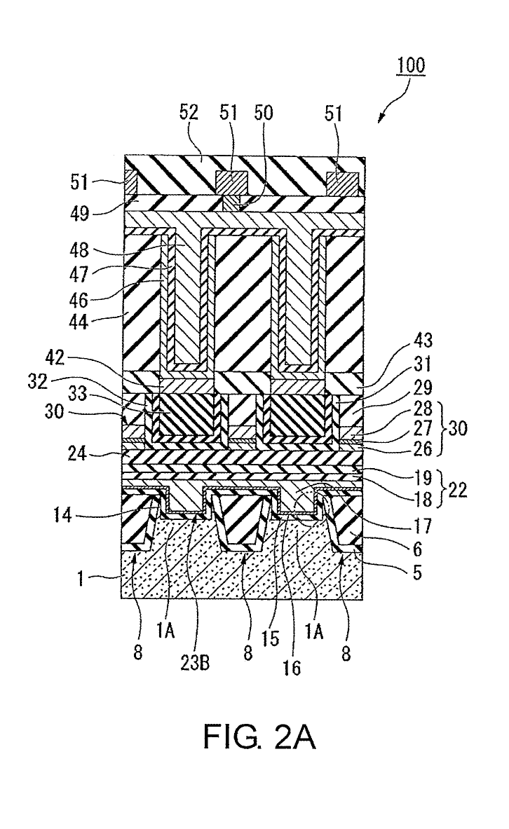

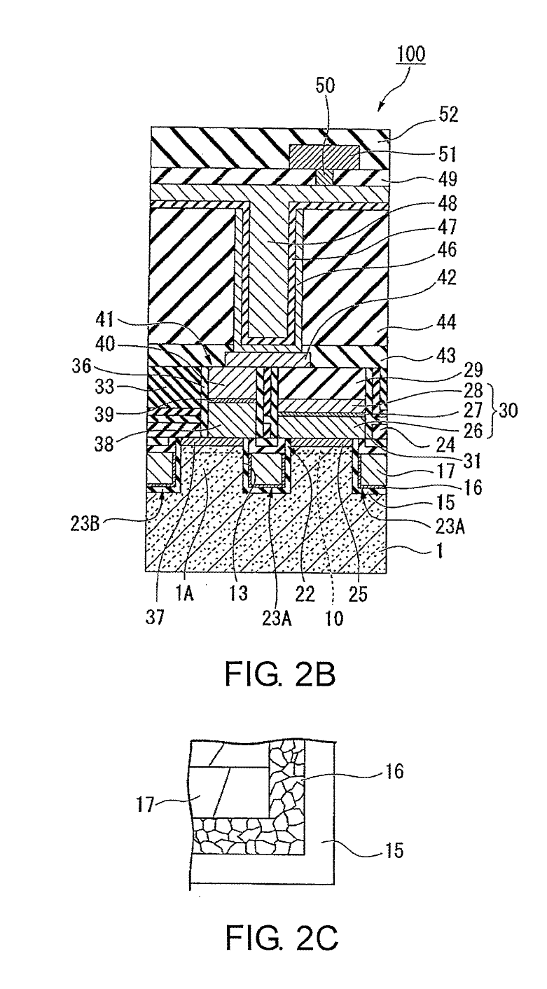

FIG. 2A and FIG. 2B are sectional views illustrating the exemplary structure of the DRAM 100 according to this embodiment. FIG. 2A is a sectional view taken along the line A-A of FIG. 1, and FIG. 2B is a sectional view taken along the line B-B of FIG. 1. FIG. 2C is an enlarged view of a portion surrounded by a two-dot chain line of FIG. 2A. In this case, FIG. 2A illustrates a section in parallel with a Y direction illustrated in FIG. 1. FIG. 2B illustrates a section which is, strictly speaking, shifted from an X direction illustrated in FIG. 1, but is, in the following description of this embodiment, regarded as a section in parallel with the X direction.

Further, in the DRAM 100 of the embodiment, a silicon substrate is used as a semiconductor substrate which is a base. Further, not only a single semiconductor substrate but also structures in the process of manufacturing a semiconductor device on the semiconductor substrate and a state in which a semiconductor device is formed on the semiconductor substrate are collectively referred to as a wafer.

Planar metal oxide semiconductor (MOS) transistors (hereinafter referred to as MOS transistors) are provided on a silicon substrate 1 of the DRAM 100, and thus, first, the structure of the MOS transistors is described. As illustrated in FIG. 1, FIG. 2A, and FIG. 2B, the MOS transistors are provided in active regions 1A surrounded by a shallow trench isolation (STI) element isolation film 8 to be an element isolation region of the silicon substrate 1. The STI element isolation film 8 is formed by stacking insulating films 5 and 6 in grooves provided in the silicon substrate 1.

As illustrated in FIG. 2A and FIG. 2B, the MOS transistor includes a gate insulating film 15 which covers inner walls of a gate electrode groove 13 provided in the active region 1A, an intervening layer 16 which covers an upper surface portion and a part of a side surface portion of the gate insulating film 15, a conductive film 17 provided inside the intervening layer 16 to be a buried gate electrode (word line) 23A and a buried wiring 23B, and an impurity diffusion layer 25 and an impurity diffusion layer 37 that are provided on a lightly doped impurity diffusion layer 10 to be a source region and a drain region.

As illustrated in FIG. 2C, in the MOS transistor of this embodiment, the intervening layer 16 is formed of a titanium nitride film containing carbon at a concentration of 3×10²⁰ to 7×10²⁰ atoms/cm³ (about 1% in content by percentage). When the carbon concentration is low, the effect of preventing diffusion of boron from a tungsten film into the semiconductor substrate is reduced. When the carbon concentration is high, the characteristics of the transistor are deteriorated, in particular, the threshold of the transistor is lowered.

The intervening layer 16 has an amorphous structure and has irregular grain boundaries. No linear grain boundary continuing from the conductive film 17 to the gate insulating film 15 exists in the intervening layer 16, and all the grain boundaries are in curves and extend irregularly in the intervening layer 16.

Further, in the MOS transistor of this embodiment, the major axis of a tungsten crystal in the conductive film 17 is, for example, about 80 nm to 120 nm, and the crystal size of tungsten (W) is about one and a half times as large as that in a conventional case. Further, the intervening layer 16 and the conductive film 17 are sequentially stacked in the gate electrode grooves 13 provided in the active regions 1A of the silicon substrate 1.

As illustrated in FIG. 2B, the lightly doped impurity diffusion layer 10 is provided above the active regions 1A except for regions in which the gate insulating film 15 is provided, and is a layer formed by diffusing impurities of the opposite conductivity type to that of conductive impurities contained in the silicon substrate 1 in a large amount. Further, as illustrated in FIG. 2A, an upper surface of the conductive film 17 is covered with a cap insulating film 22 provided by stacking a liner film 18 and a buried insulating film 19.

In the active region 1A illustrated in FIG. 2B, for the sake of convenience of description, just two MOS transistors which have the buried gate electrode (word line) 23A are illustrated. In a cell array portion in an actual DRAM, several thousands to several hundreds of thousands of MOS transistors are arranged. The buried wiring 23B illustrated in FIG. 2A and FIG. 2B has the same structure as the buried gate electrode 23A, but does not function as a word line and is a wiring which electrically isolates the MOS transistors. In the buried wiring 23B, by keeping the voltage thereof at a predetermined value, a parasitic transistor is at an off state, and thus, the adjacent MOS transistors on the same active region 1A can be isolated from each other.

Next, a structure above the above-mentioned MOS transistors is described.

As illustrated in FIG. 2A and FIG. 2B, a plurality of memory cells having the above-mentioned MOS transistors and the capacitors are provided in a cell array portion of the DRAM 100. The capacitors are cylindrical, and are each formed of a lower electrode 46, a capacitor insulating film 47, and an upper electrode 48.

The lower electrode 46 is in the shape of a cylinder having an inner wall and an outer wall. The upper electrode 48 is buried on the inner wall side of the lower electrode 46 via the capacitor insulating film 47.

The impurity diffusion layer 25 is connected to a conductive film 26 provided on the silicon substrate 1. The conductive film 26 forms, together with conductive films 27 and 28 which are provided on the conductive film 26, bit lines 30. Further, upper surfaces of the bit lines 30 are covered with a mask film 29, and side surface portions of the bit lines 30 are covered with an insulating film 31.

The impurity diffusion layer 37 is connected to the lower electrode 46 via a capacitor contact plug 41 and a capacitor contact pad 42 provided on the silicon substrate 1. In this case, the capacitor contact plug 41 has a stacked structure in which an intervening layer 39 is inserted between a conductive film 38 and a conductive film 40. Further, a side surface portion of the capacitor contact plug 41 is covered with a side wall insulating film 36.

The capacitor contact pad 42 is provided for the purpose of securing an alignment margin between the lower electrode 46 and the capacitor contact plug 41, and thus, is not necessarily required to cover the entire upper surface of the capacitor contact plug 41. Specifically, it is enough that the capacitor contact pad 42 is located above the capacitor contact plug 41 and is connected to at least a part of the upper surface of the capacitor contact plug 41.

Side surfaces of the bit lines 30, the mask film 29, and the capacitor contact plug 41 are covered with a first interlayer insulating film 24, the insulating film 31, a liner film 32, and an applied insulating film 33 (hereinafter referred to as spin on dielectrics (SOD) 33). Further, the capacitor contact pad 42 is covered with a stopper film 43 for protecting the SOD 33.

A third interlayer insulating film 44 is provided on the stopper film 43. Further, the lower electrode 46 is provided so as to pierce the third interlayer insulating film 44 and the stopper film 43. Therefore, the outer wall of the lower electrode 46 is held in contact with the third interlayer insulating film 44 and the stopper film 43. An upper surface of the third interlayer insulating film 44 is covered with the capacitor insulating film 47. Further, an exposed surface of the capacitor insulating film 47 is covered with the upper electrode 48.

The upper electrode 48 is covered with a fourth interlayer insulating film 49. Further, a contact plug 50 is provided in the fourth interlayer insulating film 49. Further, an upper metal wiring 51 is provided on the fourth interlayer insulating film 49. The upper electrode 48 is connected to the upper metal wiring 51 via the contact plug 50. The upper metal wiring 51 and the fourth interlayer insulating film 49 are covered with a protective film 52.

As described above, the MOS transistor of the embodiment has a buried word line, and has a structure which is effective in reducing the occupied area in the cell array portion compared with a case of a planar MOS transistor. Generally, as the occupied area is reduced, the components of the MOS transistor are required to be downsized accordingly, and side effects of the downsizing cause malfunctions of the MOS transistor. For example, when the width of the buried word line is reduced, the resistance of the wiring increases, and thus, there is a problem that signal delay is caused in the MOS transistor. In the embodiment, the tungsten film having enlarged grain boundaries and a low resistance is used.

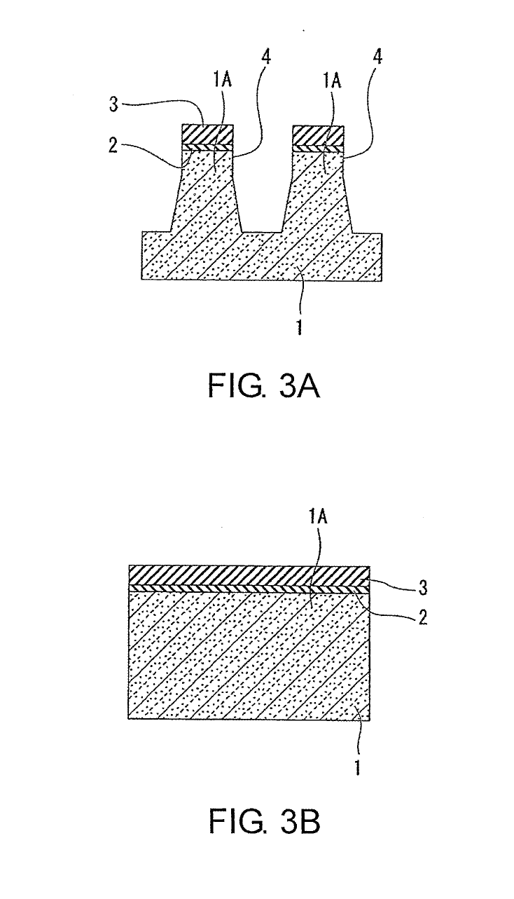

Next, a method of manufacturing the semiconductor device of the embodiment is described with reference to the attached drawings. FIG. 3A to FIG. 27A are sectional views taken along the line A-A of FIG. 1, and FIG. 3B to FIG. 27B are sectional views taken along the line B-B of FIG. 1. Further, similarly to FIG. 2A and FIG. 2B, FIG. 3A to FIG. 27A illustrate sections in parallel with the Y direction illustrated in FIG. 1, and FIG. 3B to FIG. 27B are regarded as sections in parallel with the X direction illustrated in FIG. 1.

First, as illustrated in FIG. 3A and FIG. 3B, on a P-type silicon substrate 1, a sacrificial film 2 which is a silicon oxide film (SiO₂) and a mask film 3 which is a silicon nitride film (Si₃N₄) are deposited in sequence by, for example, thermal oxidation and by, for example, thermal chemical vapor deposition (thermal CVD), respectively. Then, the mask film 3, the sacrificial film 2, and the silicon substrate 1 are patterned using photolithography and dry etching to form element isolation grooves 4 (trenches) for defining the active regions 1A in the silicon substrate 1. The element isolation grooves 4 are formed to have a width of about 20 nm and a depth of about 250 nm as linear patterns extending in the X direction. Further, regions to be the active regions 1A after the element isolation grooves 4 are formed are covered with the mask film 3.

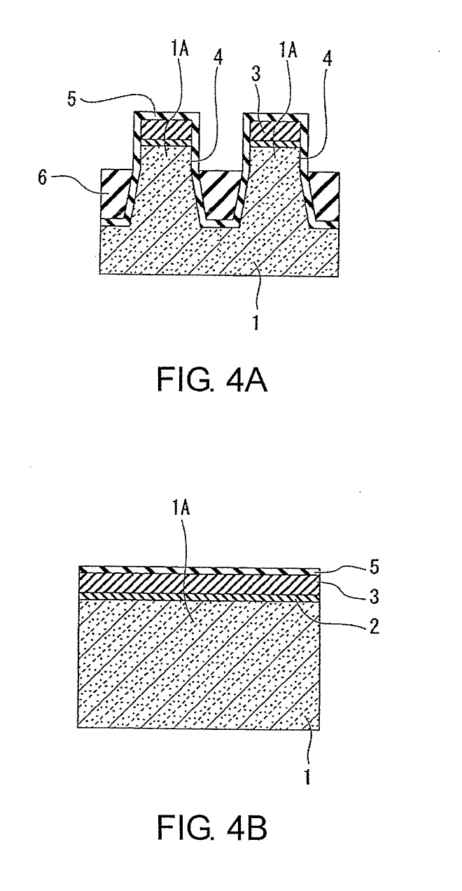

Next, as illustrated in FIG. 4A and FIG. 4B, the insulating film 5 which is a silicon oxide film is formed by, for example, thermal oxidation, so as to cover the surfaces of the silicon substrate 1 and the mask film 3 which are exposed in the element isolation grooves 4. After that, the insulating film 6 which is a silicon nitride film is deposited by, for example, thermal CVD, so as to fill the element isolation grooves 4, and then, etching back is carried out so as to leave the insulating film 6 only in the element isolation grooves 4.

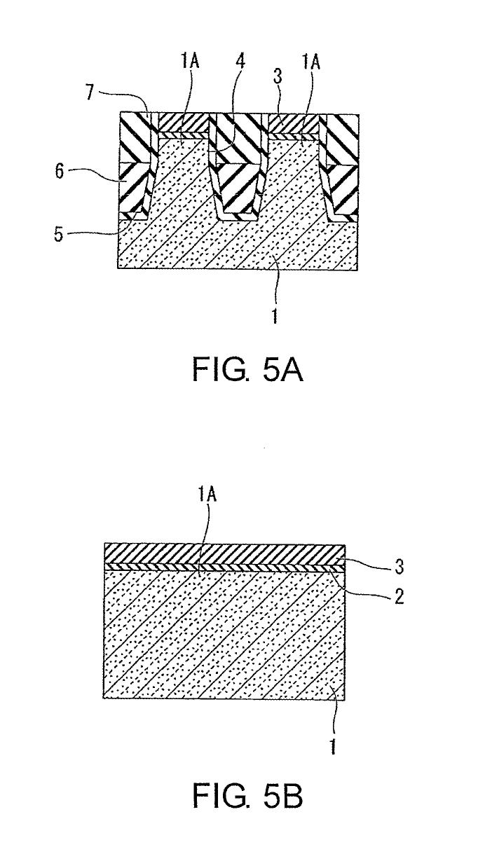

Next, as illustrated in FIG. 5A and FIG. 5B, the buried film 7 which is a silicon oxide film is deposited by, for example, plasma CVD, so as to fill the element isolation grooves 4. Then, chemical mechanical polishing (CMP) is carried out until the mask film 3 is exposed to planarize the surface of the buried film 7.

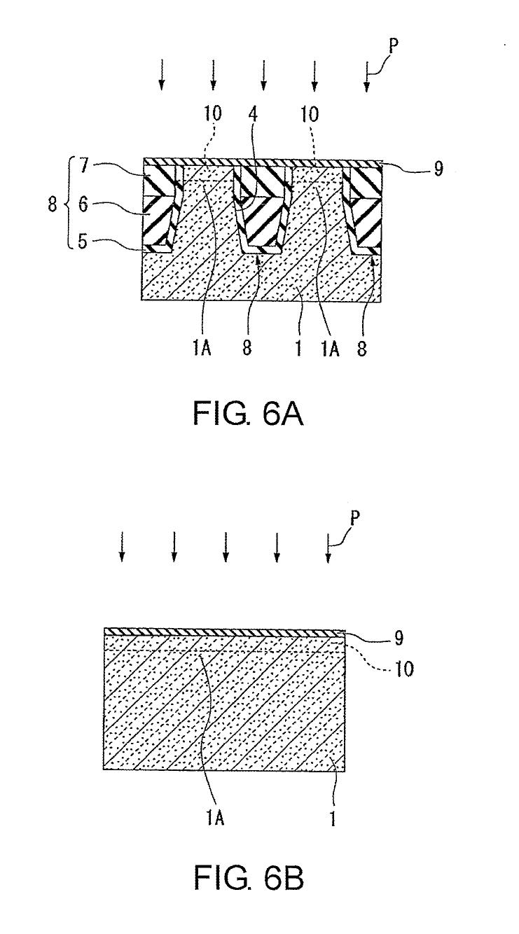

Next, as illustrated in FIG. 6A and FIG. 6B, the mask film 3 and the sacrificial film 2 are removed by, for example, wet etching, so that the surface of the buried film 7 in the element isolation grooves 4 and the surface of the silicon substrate 1 are substantially flush with each other. In this way, the STI element isolation film 8 which forms the element isolation region is formed. By the element isolation region using the STI element isolation film 8, the active regions 1A are defined and formed in the silicon substrate 1.

Next, a sacrificial film 9 which is a silicon oxide film is formed by, for example, thermal oxidation, on the exposed surface of the silicon substrate 1. Then, as low concentration N-type impurities, phosphorus (P) or the like is implanted by ion implantation into the silicon substrate 1 to form the N-type lightly doped impurity diffusion layer 10. The lightly doped impurity diffusion layer 10 functions as (a part of) a source/drain (S/D) region of the transistor.

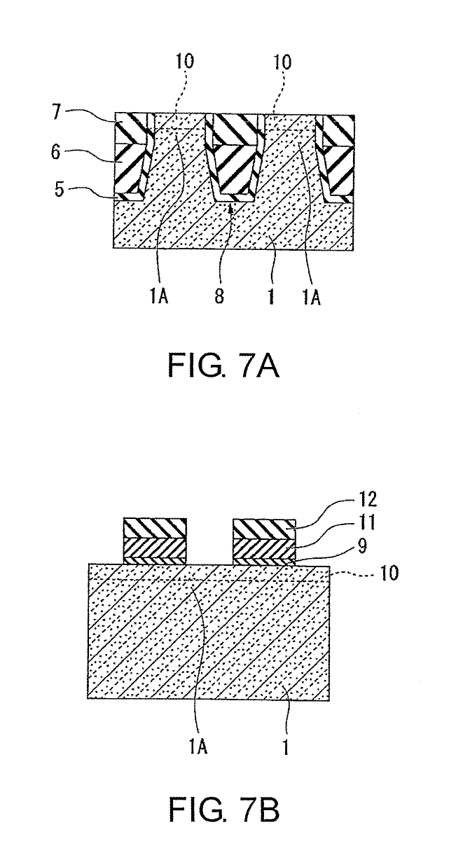

Next, as illustrated in FIG. 7A and FIG. 7B, a lower layer mask film 11 which is a silicon nitride film is formed by, for example, CVD, on the sacrificial film 9. After an upper layer mask film 12 which is a carbon film (amorphous carbon film) is deposited by plasma CVD on the lower layer mask film 11, patterning is carried out to form the patterns of the gate electrode grooves (trenches) 13.

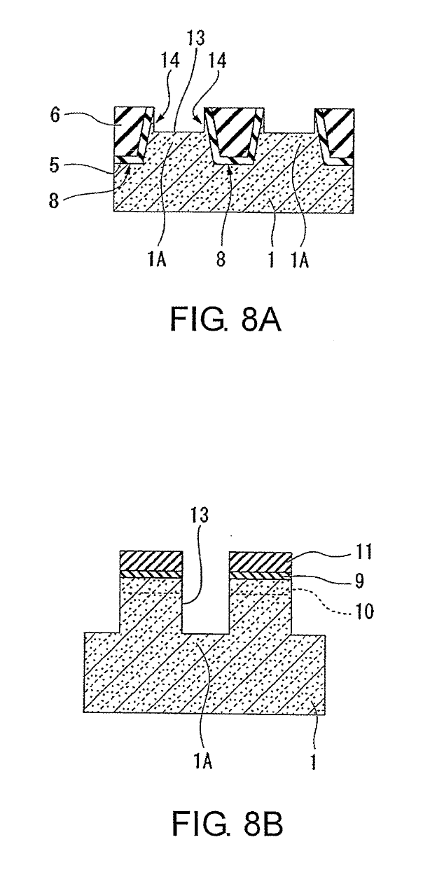

Next, as illustrated in FIG. 8A and FIG. 8B, the exposed silicon substrate 1 is etched by dry etching to form the gate electrode grooves (trenches) 13. The gate electrode grooves 13 are formed as linear patterns extending in the Y direction intersecting with the active regions 1A. Thin film-like silicon portions 14 remain in the shape of side walls on the gate electrode grooves 13 in side surface parts held in contact with the STI element isolation film 8, which function as (a part of) a channel region of the transistor. Further, at least a part of the lower layer mask film 11 is left on the silicon substrate 1 except for the inside of the gate electrode grooves 13.

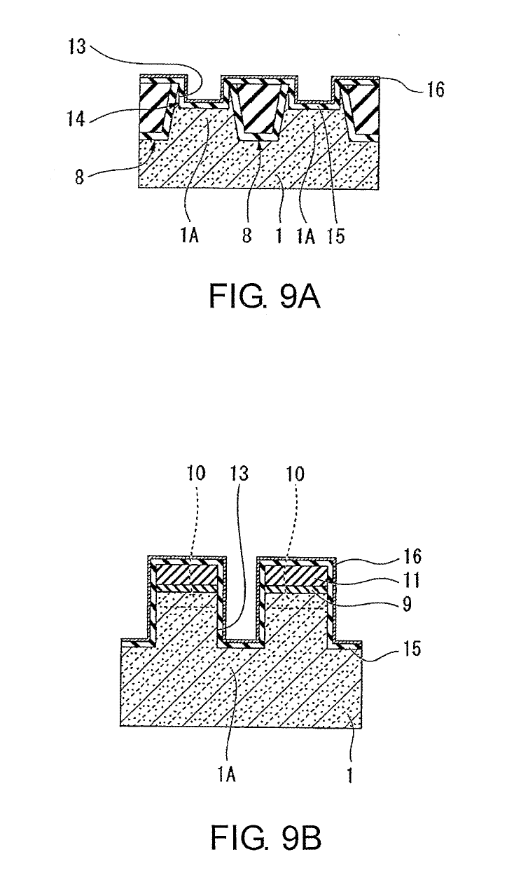

Then, as illustrated in FIG. 9A and FIG. 9B, the gate insulating film 15 is formed so as to cover inner wall surfaces of the gate electrode grooves 13 and the surface of the substrate. As the gate insulating film 15, for example, a silicon oxide film formed by thermal oxidation can be used. The thickness of the gate insulating film 15 can be, when a silicon oxide film is used therefor, for example, 5 nm.

Next, a titanium nitride (TiN) film is formed by, for example, atomic layer deposition (ALD), on the gate insulating film 15 to form the intervening layer 16. The thickness of the intervening layer 16 (that is, the thickness of the titanium nitride film) can be, for example, 3 to 5 nm.

By the way, ALD is a method for forming a titanium nitride film on a semiconductor substrate which is kept at a predetermined temperature by repeating a plurality of times a cycle of processing including (1) supplying a material gas, (2) adsorbing the material gas onto the semiconductor substrate, (3) discharging the material gas in excess by vacuum purge, (4) supplying an added gas, (5) causing the material gas to react with the added gas, and (6) discharging the added gas in excess by vacuum purge.

Exemplary process conditions in a cycle are as follows. After tetrakis dimethyl amino titanium (TDMAT: Ti[N(CH₃)₂]₄) as the material gas is supplied at a flow rate of 600 to 1,200 standard cubic centimeter per minute (sccm) into a chamber having a pressure of 3 to 5 Torr at a temperature of 340 to 400° C., nitrogen (N₂) as the added gas is supplied at a flow rate of 2 to 4 standard liter per minute (slm).

Under these process conditions, TDMAT becomes titanium nitride (TiN) mainly by the following first reaction and second reaction.

Ti[N(CH₃)₂]₄→Ti[N(CH₃)₂]₂*+HN(CH₃)₂+H₂(NCH₃)+C first reaction:

Ti[N(CH₃)₂]₂*+N*→*TiN+N₂+C₂H₆+2CH₃N second reaction:

In the above-mentioned first reaction, by thermally decomposing by heating TDMAT at 400° C., an intermediate in an active state (Ti[N(CH₃)₂]₂*) is formed. In the subsequent second reaction, when nitrogen (N₂) as the added gas is supplied, nitrogen (N₂) also enters an active state (N*), and reacts with the intermediate (Ti[N(CH₃)₂]₂*) to form desired titanium nitride (TiN).

When titanium nitride (TiN) is formed, carbon (C) is formed as a by-product of the first reaction to be contained in titanium nitride (TiN) formed in the subsequent second reaction. Highly pure titanium nitride (TiN) is a cylindrical crystal. However, when carbon (C) is contained as an impurity, crystal growth of titanium nitride (TiN) is inhibited by carbon (C), and thus, titanium nitride (TiN) becomes amorphous.

Under these process conditions, the intervening layer 16 at a thickness of 0.05 to 0.3 nm can be formed per minute, and thus, in order to obtain the intervening layer 16 at a thickness of 3 nm, it takes 10 to 60 minutes. ALD is a method for forming a film based on adsorption of a material gas onto a surface of a silicon substrate and chemical reaction of the adsorbed material. ALD is a process in which a monolayer film can be formed without stacking film-forming molecules, and thus, suitable for controlling the film thickness with high accuracy.

The method of forming the intervening layer 16 (that is, the method of forming the titanium nitride film) is not limited to ALD described above, and, for example, CVD may also be used.

Exemplary process conditions in the case of CVD are as follows. TDMAT (Ti[N(CH₃)₂]₄), nitrogen (N₂), and hydrogen (H₂) are used as the material gases. The material gases are supplied at flow rates of 600 to 1,200 sccm (TDMAT) and 2 to 3 slm (N₂ and H₂) into a chamber having a pressure of 3 to 5 Torr at a temperature of 400° C., and the bias power is 1 to 2 kW. In this manner, the titanium nitride film may be formed.

Also in CVD, carbon (C) is formed by thermal decomposition of TDMAT to be contained in titanium nitride (TiN), and thus, the intervening layer 16 which is an amorphous titanium nitride (TiN) film can be formed.

The titanium nitride film contains carbon at a concentration of 3×10²⁰ to 7×10²⁰ atoms/cm³ (about 1% in content by percentage). This means that the intervening layer 16 contains carbon at a concentration of 3×10²⁰ to 7×10²⁰ atoms/cm³ (about 1% in content by percentage).

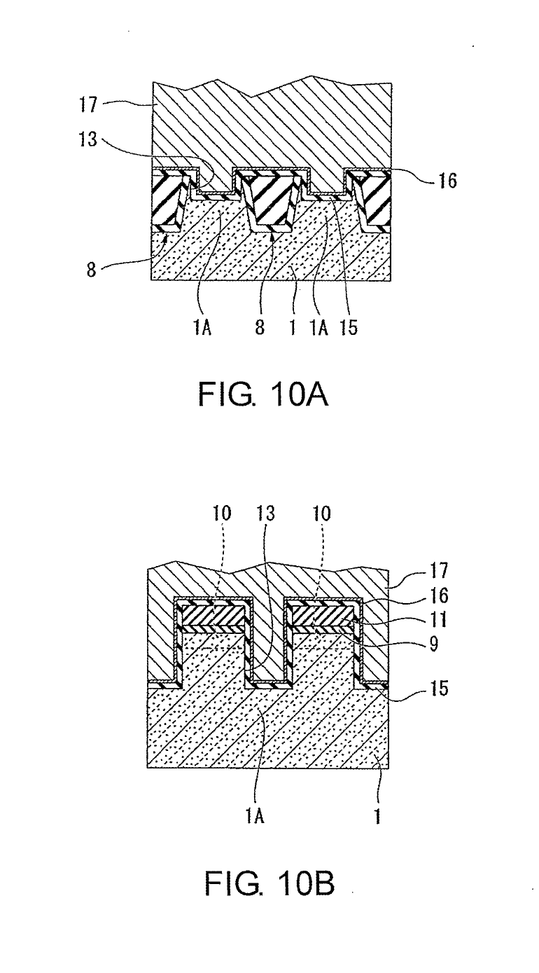

Next, as illustrated in FIG. 10A and FIG. 10B, the conductive film 17 which is a tungsten (W) film (also referred to as a tungsten layer) is formed at a thickness of 30 to 60 nm. The conductive film 17 can be formed in, for example, the following two steps. First, in a first step, a nucleus of tungsten (W) is formed by sequential flow deposition (SFD). Secondly, in a second step, a tungsten (W) film (tungsten layer) is grown by CVD with the nucleus formed in the first step being a starting point.

The film forming conditions in the first step are as follows. Tungsten hexafluoride (WF₆) and diborane (B₂H₆) are used as the material gases. For example, the flow rates of the material gases are 100 to 500 sccm (WF₆) and 500 to 1,000 sccm (B₂H₆), the temperature of the heated substrate is 350 to 400° C., and the pressure in the reaction chamber is 100 Torr. In this case, based on the following reaction formula (1), tungsten hexafluoride (WF₆) is reduced by diborane (B₂H₆) to be a crystal nucleus of tungsten (W):

WF₆+B₂H₆→W+6HF+2B (1)

The film forming conditions in the second step are as follows. Tungsten hexafluoride (WF₆) and hydrogen (H₂) are used as the material gases. For example, the flow rates of the material gases are 300 to 500 sccm (WF₆) and 3 to 4 slm (H₂), the temperature of the heated substrate is 350 to 400° C., and the pressure in the reaction chamber is 100 Torr. In this case, based on the following reaction formula (2), tungsten hexafluoride (WF₆) is reduced by hydrogen (H₂) to grow as tungsten (W) having a major axis of 80 nm to 120 nm:

WF₆+3H₂→W+6HF (2)

By the way, in a conventional method of forming a conductive film (tungsten film), tungsten hexafluoride (WF₆) and monosilane (SiH₄) are used as the material gases in the first step. When monosilane is used as a material gas, as expressed by the following reaction formula (3), tungsten hexafluoride is reduced by monosilane to be a crystal nucleus of tungsten (W):

2WF₆+3SiH₄→2W+12HF+3Si (3)

Next, in the second step in which tungsten hexafluoride (WF₆) and hydrogen (H₂) are used as the material gases, as expressed by the reaction formula (2), tungsten hexafluoride (WF₆) is reduced by hydrogen (H₂) to grow as tungsten (W).

However, when tungsten (W) obtained through reduction of tungsten hexafluoride by monosilane is used as a crystal nucleus, the crystal nucleus of tungsten grows so that the crystal has a major axis of about 60 nm to 80 nm.

On the other hand, according to the method of forming the conductive film 17 used in the embodiment, tungsten hexafluoride (WF₆) and diborane (B₂H₆) are used as the material gases in the first step to form a crystal nucleus of tungsten (W), and thus, the crystal nucleus of tungsten grows in the second step so that the crystal has a major axis of about 80 nm to 120 nm. Therefore, tungsten (W) can be grown to have a crystal size of about one and a half times as large as the case in the conventional method (see FIG. 2C).

Further, according to the method of forming the conductive film 17 used in the embodiment, diborane (B₂H₆) is used as a material gas in the first step, and thus, as expressed by the reaction formula (1), boron (B) is formed as a by-product in the first step to be contained in the formed tungsten film.

Generally, when boron is contained in a tungsten film which forms the conductive film 17, boron may pass through the intervening layer 16 which is a titanium nitride (TiN) film and may further pass through the gate insulating film 15 to diffuse in the silicon substrate 1. In this case, when unnecessary boron (B) in the tungsten film diffuses in the silicon substrate 1 to be taken in the channel region of the transistor, there is a problem that operation of the transistor becomes unstable.

However, the intervening layer 16 used in the embodiment is, as described above, a titanium nitride (TiN) film containing carbon (C). The titanium nitride (TiN) film containing carbon is in an amorphous state and has grain boundaries extending irregularly therein. On the other hand, boron (B) moves along grain boundaries, and thus, cannot pass through the intervening layer 16 containing carbon, in which grain boundaries extend irregularly. Therefore, boron (B) contained in the tungsten film as the conductive film 17 does not diffuse in the silicon substrate 1.

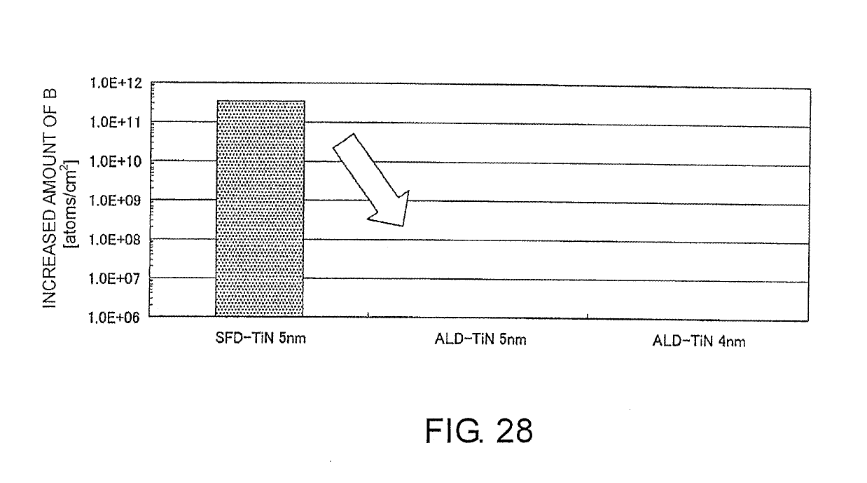

FIG. 28 is a graph showing the relationship between the manufacturing method and thickness of the titanium nitride (TiN) film and the number of boron (B) atoms per unit area which have reached the silicon substrate through the intervening layer and the gate insulating film. Specifically, the result of a case in which a titanium nitride film is formed at a thickness of 5 nm by SFD corresponding to the conventional method, and the result of cases in which a titanium nitride film is formed at thicknesses of 5 nm and 4 nm by ALD described in this embodiment are shown. Note that, the number of boron (B) atoms per unit area which have reached the silicon substrate is determined by measuring the numbers of boron (B) atoms in the silicon substrate 1 before and after the conductive film 17 which is a tungsten (W) film is formed by secondary ion mass spectrometry (SIMS), and then calculating the difference therebetween and converting the difference into a number per unit area.

As shown in FIG. 28, in the case in which a titanium nitride film is formed at a thickness of 5 nm by SFD corresponding to the conventional method, necessary carbon is not contained in the titanium nitride film, and thus, boron (B) contained in the conductive film which is a tungsten film reaches the silicon substrate through the intervening layer and the gate insulating film. On the other hand, in the case in which a titanium nitride film is formed at a thickness of 5 nm by ALD described in this embodiment, the titanium nitride film contains necessary carbon and has grain boundaries extending irregularly therein, and thus, boron is less liable to pass through the intervening layer and diffusion of boron (B) in the silicon substrate 1 can be prevented. Further, the titanium nitride (TiN) film formed by ALD can prevent diffusion of boron (B) even when the thickness of the film is as small as 4 nm. These effects can be similarly obtained by titanium nitride (TiN) formed by CVD insofar as necessary carbon is contained in the titanium nitride film.

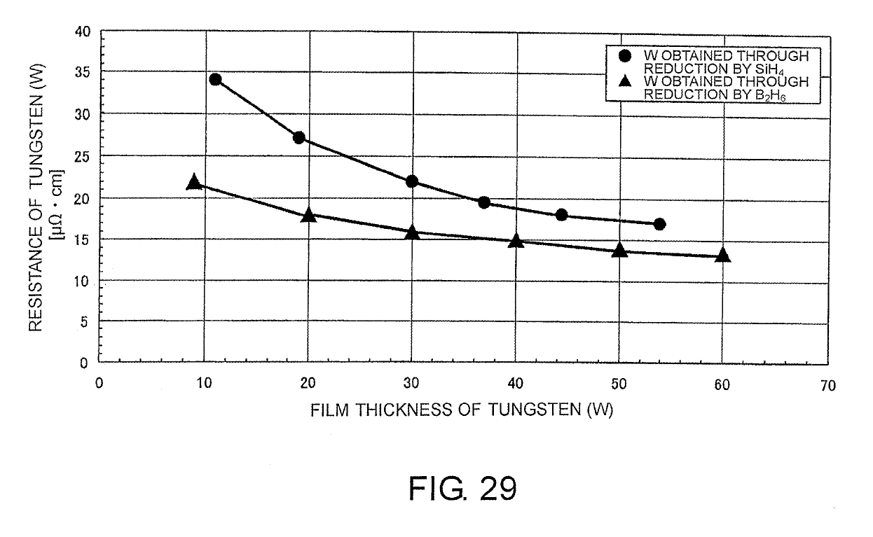

FIG. 29 is a graph showing the relationship between the thickness and the electrical resistivity of a tungsten film formed by using tungsten hexafluoride and diborane as the material gases in the first step to form a crystal nucleus of tungsten and growing the crystal nucleus (a case of this embodiment) and, the relationship between the thickness and the electrical resistivity of a tungsten film formed by using tungsten hexafluoride and monosilane as the material gases in the first step to form a crystal nucleus of tungsten (W) and growing the crystal nucleus (a conventional case).

As shown in FIG. 29, in both of the case of this embodiment and the conventional case, the electrical resistivity is reduced as the film thickness increases. Specifically, as the thickness of the tungsten film increases, crystals of tungsten grow and the number of the crystals in the film thickness direction is reduced to reduce crystal interfaces which are a cause of increase in electrical resistivity. Further, in the tungsten film according to this embodiment, the particle diameter of a tungsten crystal is larger than that of the tungsten film in the conventional case. Therefore, the electrical resistivity of each of the tungsten films according to this embodiment having the thicknesses shown in FIG. 29 is lower than that of the tungsten film in the conventional case. For example, when the thickness of the tungsten film is 50 nm, the electrical resistivity in the case of this embodiment is lower by about 25% than that in the conventional case.

As illustrated in FIG. 10A and FIG. 10B, the surface of the conductive film 17 which is a tungsten film is not planarized but uneven, and the height difference within a wafer surface is about 40 nm at the maximum.

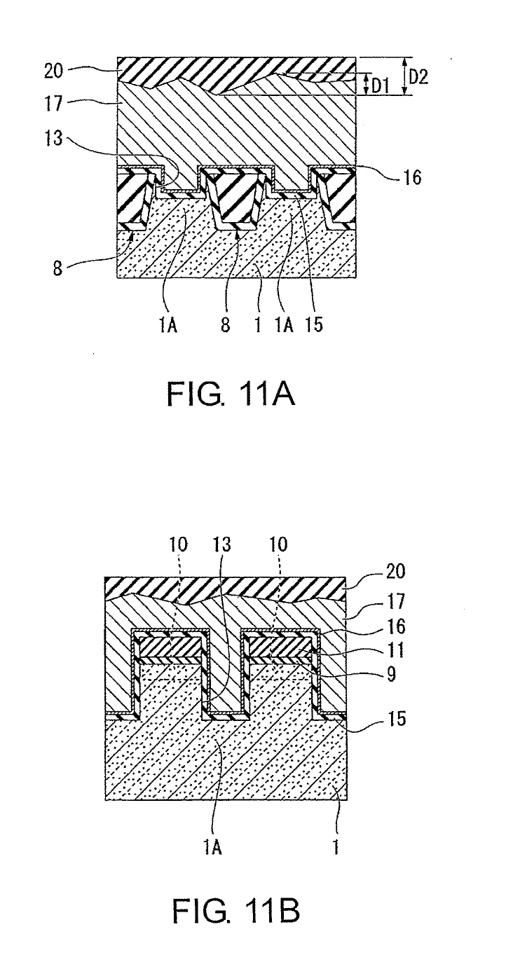

Next, as illustrated in FIG. 11A and FIG. 11B, a cover film 20 is formed so as to cover the conductive film 17. The cover film 20 can be formed by, for example, applying a polymer material onto the conductive film 17. The polymer material is not specifically limited insofar as the polymer material can be applied onto the conductive film 17. As such a polymer material, for example, a bottom anti reflective coating (BARC) containing, as a main component, a novolac-based polyphenol resin dissolved in an organic solvent can be used.

Assuming that the maximum height of the uneven surface of the conductive film 17 is D1 and the thickness of the cover film 20 after the film formation is D2, it is preferred that the thickness of the polymer material applied onto the conductive film 17 be such that D2 is 40 nm which is about twice as large as D1. As a result, the polymer material flows so as to bury the unevenness on the surface of the conductive film 17, and thus, the surface of the cover film 20 after the polymer material is applied becomes planarized. After that, in order to inhibit the flowability of the cover film 20, for example, baking is carried out at about 175 to 240° C. for 60 to 90 seconds to volatilize the organic solvent.

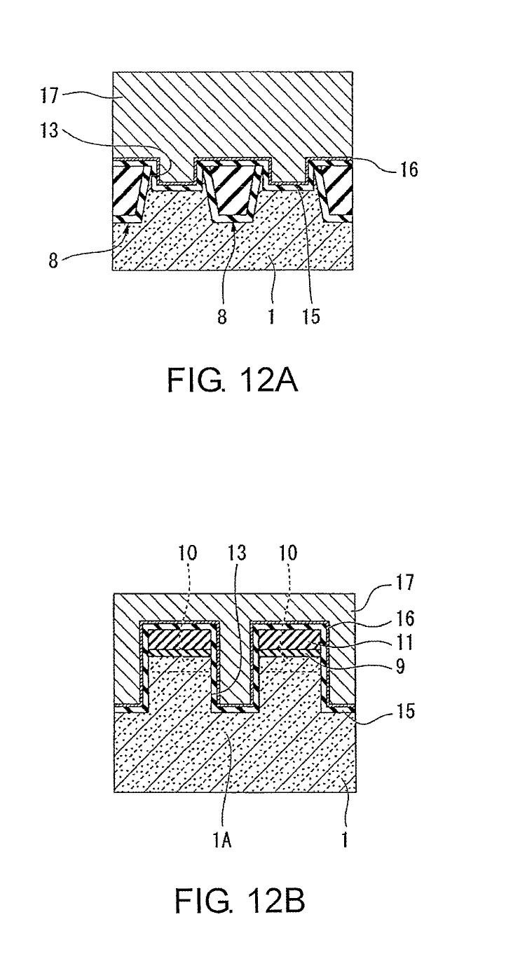

Next, as illustrated in FIG. 12A and FIG. 12B, by completely removing the cover film 20 by, for example, dry etching, the upper surface of the conductive film 17 is exposed. As the dry etching of the cover film 20, for example, reactive ion etching (RIE) using inductively coupled plasma (ICP) can be used. Further, the dry etching conditions can be, for example, as follows. Sulfur hexafluoride (SF₆), oxygen (O₂), and argon (Ar) are used as process gases and the flow rates thereof are set to be 70 sccm (SF₆), 30 sccm (O₂), and 120 sccm (Ar). The source power is set to be 600 to 1,200 W, the high frequency power is set to be 50 to 200 W, and the pressure is set to be 4 to 20 mTorr.

In the dry etching under these conditions, the selectivity ratio between the conductive film 17 and the cover film 20 is 1. Therefore, even if the conductive film 17 and the cover film 20 are to be etched in a mixed manner, the conductive film 17 and the cover film 20 can be simultaneously removed without difference in etching rate, and thus, the surface of the conductive film 17 to be left can be planarized.

In this case, it is preferred that the conductive film 17 left on the intervening layer 16 have a thickness of 10 nm or more so as not to expose the intervening layer 16 resulting in oxidation of the intervening layer 16. The height (thickness) of the remaining conductive film 17 can be controlled by the duration of the dry etching.

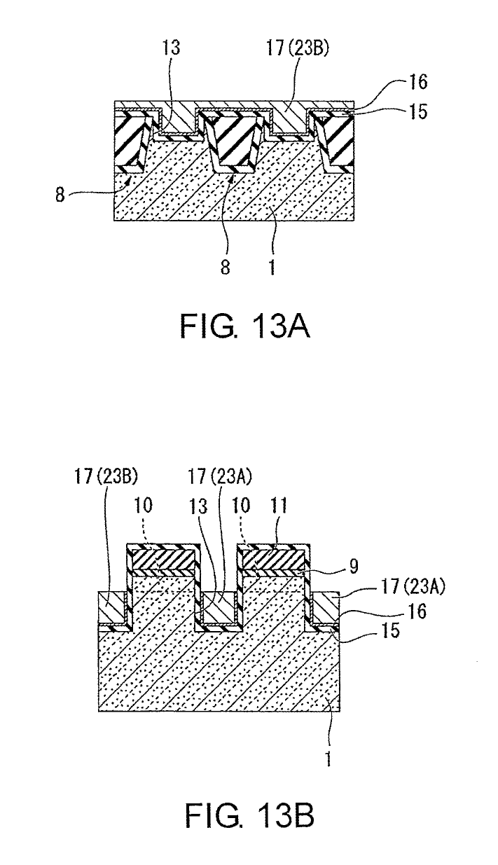

Next, as illustrated in FIG. 13A and FIG. 13B, an upper portion of the conductive film 17 is removed by, for example, dry etching, so that the thickness of the conductive film 17 left at the bottom of the gate electrode grooves 13 is about 50 nm. As the dry etching of the conductive film 17, for example, RIE using ICP can be used. The dry etching conditions can be, for example, as follows. Sulfur hexafluoride (SF₆) and argon (Ar) are used as process gases and the flow rates thereof are set to be 60 sccm (SF₆) and 160 sccm (Ar). The source power is set to be 300 W, the high frequency power is set to be 0 W, and the pressure is set to be 4 to 20 mTorr.

In the dry etching under these conditions, the high frequency power is 0 W and no bias is applied to the wafer. The selectivity ratio of the conductive film 17 to the intervening layer 16 and the gate insulating film 15 is 6 or more, and thus, the conductive film 17 can be left only at the bottom of the gate electrode grooves 13. The height (thickness) of the conductive film 17 left at the bottom of the gate electrode grooves 13 can be controlled by the duration of the dry etching.

Next, as illustrated in FIG. 13B, portions of the intervening layer 16 exposed on the surface are removed by, for example, dry etching, so that the remaining intervening layer 16 is flush with the surface of the conductive film 17 at the bottom of the gate electrode grooves 13. As the dry etching of the intervening layer 16, for example, RIE using ICP can be used. The dry etching conditions can be, for example, as follows. Chlorine (Cl₂) and argon (Ar) are used as process gases and the flow rates thereof are set to be 140 sccm (Cl₂) and 60 sccm (Ar). The source power is set to be 100 to 700 W, the high frequency power is set to be 0 W, and the pressure is set to be 4 to 20 mTorr.

In the dry etching under these conditions, the high frequency power is 0 W and no bias is applied to the wafer. The selectivity ratio of the intervening layer 16 to the lower layer mask film 11 and the gate insulating film 15 is 6 or more, and thus, the intervening layer 16 can be easily left only between the bottom of the gate electrode grooves 13 and the conductive film 17. The height (thickness) of the intervening layer 16 left between the bottom of the gate electrode grooves 13 and the conductive film 17 can be controlled by the duration of the dry etching.

By combining these kinds of dry etching, the buried gate electrode 23A and the buried wiring 23B in which the surfaces of the intervening layer 16 and the conductive film 17 are flush with each other can be formed at the bottom of the gate electrode grooves 13 (see FIG. 13B).

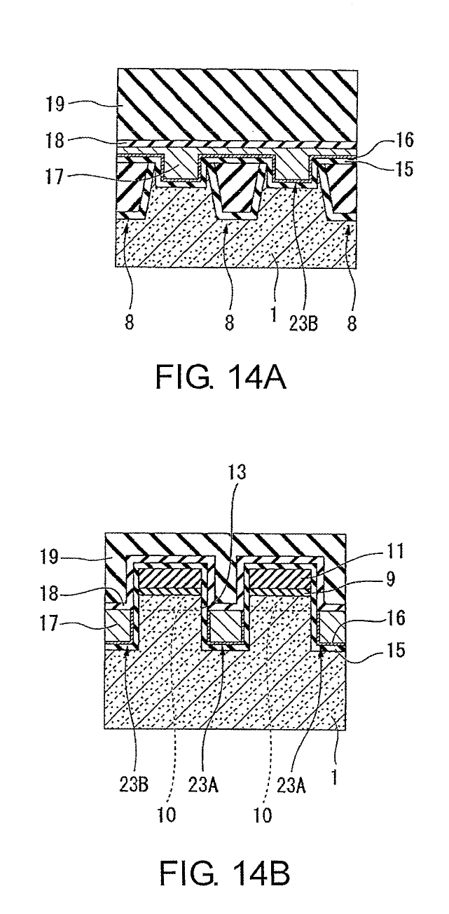

Next, as illustrated in FIG. 14A and FIG. 14B, the liner film 18 which is a silicon nitride film is formed by, for example, thermal CVD, so as to cover the upper surface of the conductive film 17 and the inner walls of the gate electrode grooves 13. Then, the buried insulating film 19 is deposited on the liner film 18. As the buried insulating film 19, for example, a silicon oxide film formed by plasma CVD, an SOD film which is an applied film, or a stacked film thereof can be used, but this invention is not limited thereto. When an SOD film is used as the buried insulating film 19, the film is modified into a solid film by annealing in a high temperature water vapor (H₂O) atmosphere.

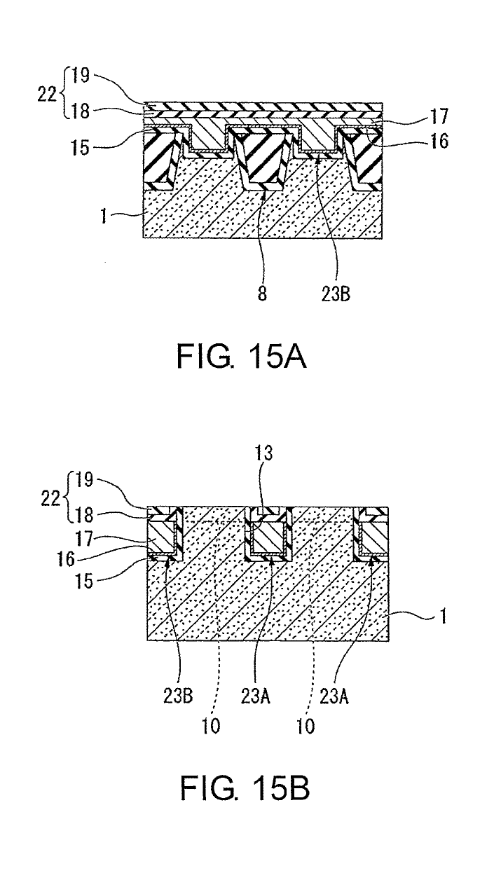

Next, as illustrated in FIG. 15A and FIG. 15B, the buried insulating film 19 is removed by, for example, CMP, until the liner film 18 formed on the lower layer mask film 11 is exposed to planarize the surface of the silicon substrate 1. Next, the lower layer mask film 11 and a part of the buried insulating film 19 and a part of the liner film 18 are removed by, for example, etching, so that the surface of the silicon substrate 1 is exposed and so that an upper surface of the buried insulating film 19 is substantially flush with the surface of the silicon substrate 1. In this way, the cap insulating film 22 including the liner film 18 and the buried insulating film 19 is formed on the buried gate electrode (word line) 23A and the buried wiring 23B. Further, by the cap insulating film 22, upper surfaces of the buried gate electrode 23A and the buried wiring 23B are insulated.

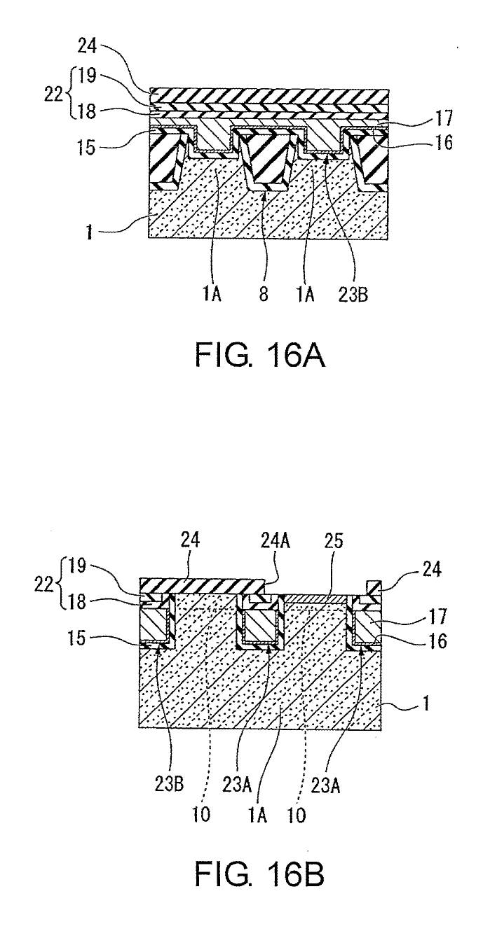

Next, as illustrated in FIG. 16A and FIG. 16B, the first interlayer insulating film 24 which is a silicon oxide film or the like is formed by, for example, plasma CVD, so as to cover the silicon substrate 1. Next, a part of the first interlayer insulating film 24 is removed using photolithography and dry etching to form a bit contact opening 24A. The bit contact opening 24A is formed as a linear opening pattern extending in the Y direction, similarly to the buried gate electrode 23A and the buried wiring 23B. As illustrated in FIG. 16B, the surface of the silicon substrate 1 is exposed at portions at which the pattern of the bit contact opening 24A and the active regions 1A intersect with each other. After the bit contact opening 24A is formed, N-type impurities (arsenic or the like) are ion implanted in the surface of the silicon substrate 1 which is exposed from the bit contact opening 24A to form the N-type impurity diffusion layer 25 in proximity to the surface of the silicon substrate 1. The N-type impurity diffusion layer 25 functions as a source/drain region of the transistor.

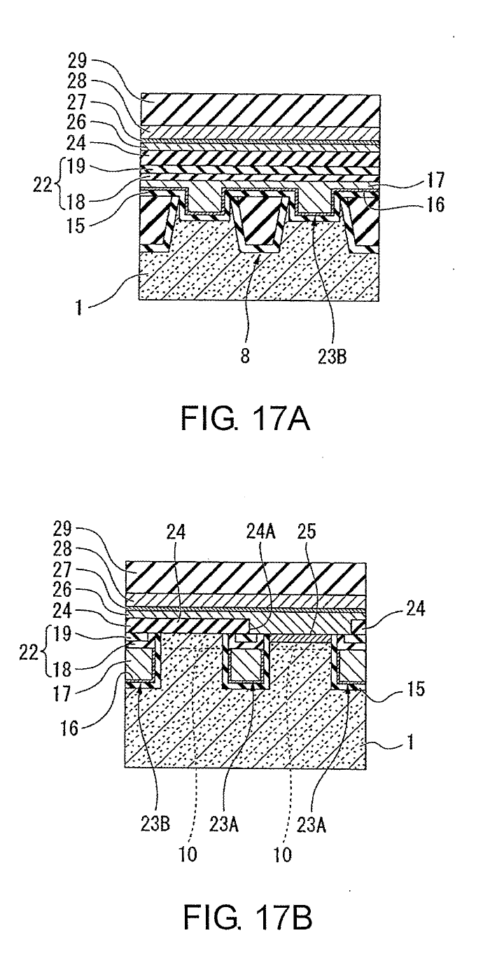

Next, as illustrated in FIG. 17A and FIG. 17B, the conductive film 26 which is a polysilicon film containing N-type impurities (phosphorus or the like) is formed by, for example, thermal CVD, so as to cover an upper surface of the impurity diffusion layer 25, the inside of the bit contact opening 24A, and the first interlayer insulating film 24. Then, the conductive film 27 which is a tungsten silicide (WSi) film and the conductive film 28 which is a tungsten film are formed by, for example, sputtering on the conductive film 26, and further, the mask film 29 which is a silicon nitride film is subsequently deposited and formed thereon by, for example, plasma CVD.

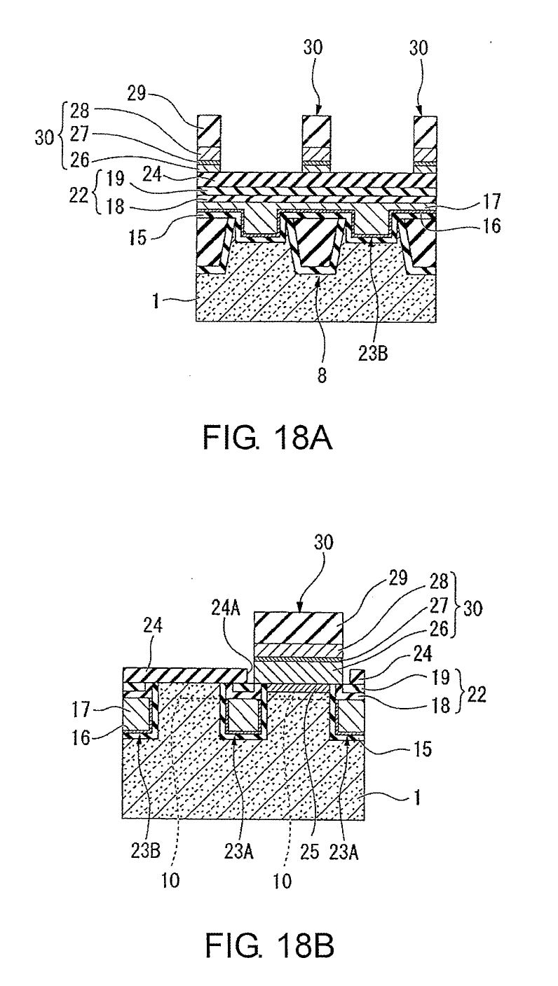

Next, as illustrated in FIG. 18A and FIG. 18B, the stacked film including the conductive film 26, the conductive film 27, the conductive film 28, and the mask film 29 is patterned in the shape of lines to form the bit lines 30 including the conductive film 26, the conductive film 27, and the conductive film 28. Note that, the bit lines 30 hereinafter referred to may include the mask film 29. The bit lines 30 are formed as patterns extending in the X direction intersecting with the buried gate electrodes 23A and the buried wirings 23B.

In FIG. 1, the bit lines 30 are illustrated in the shape of straight lines orthogonal to the buried gate electrodes 23A and the buried wirings 23B, but this invention is not limited thereto, and, for example, the bit lines 30 may be arranged in a partly-curved shape.

In the bit contact opening 24A, the conductive film 26 which forms a lower layer in the bit lines 30 and the impurity diffusion layer 25 (one of the source/drain regions) are connected to each other at an exposed surface portion of the silicon substrate 1.

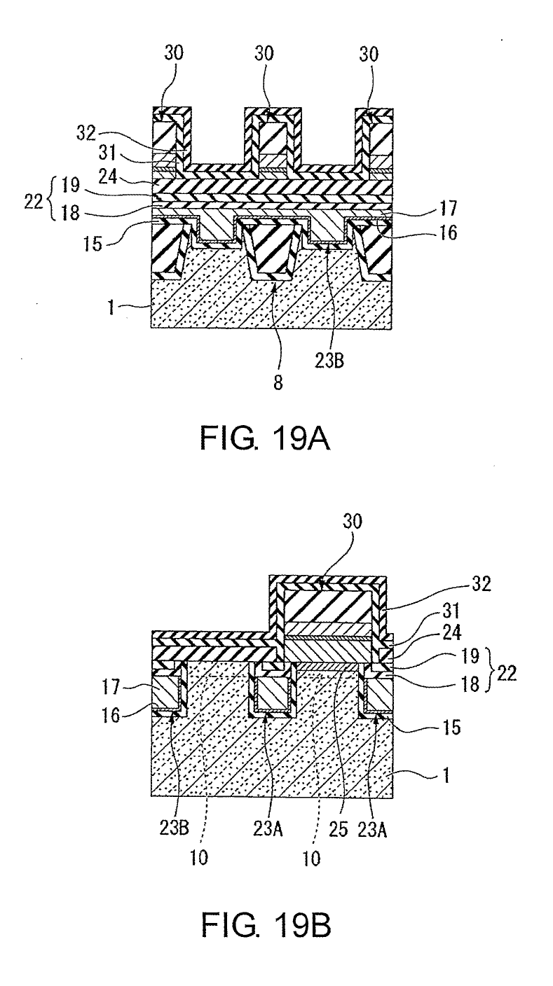

Next, as illustrated in FIG. 19A and FIG. 19B, the insulating film 31 which is a silicon nitride film is formed by, for example, thermal CVD, so as to cover the surface of the first interlayer insulating film 24 and side surfaces of the bit lines 30. Then, the liner film 32 which is a silicon nitride film or the like is formed by, for example, thermal CVD, so as to cover an upper surface of the insulating film 31. Note that, the bit lines 30 also serve as gate electrodes of planar MOS transistors in a peripheral circuit portion, and the insulating film 31 which covers the side surfaces of the bit lines 30 is used as a part of side walls of the gate electrodes in the peripheral circuit portion.

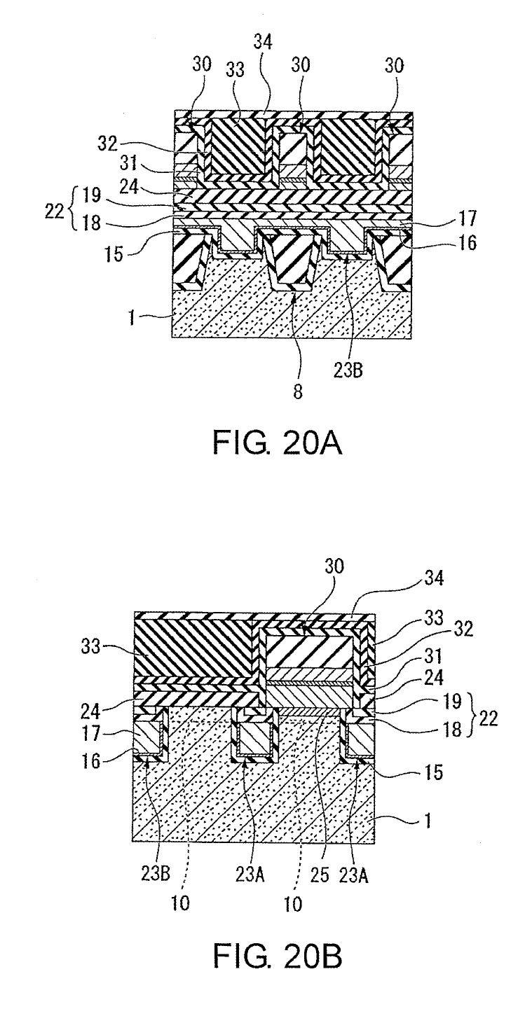

Next, as illustrated in FIG. 20A and FIG. 20B, after SOD is applied onto the liner film 32 so as to fill space between the bit lines 30, annealing is carried out in a water vapor (H₂O) atmosphere to modify the SOD into a solid film to form the SOD film 33. Then, CMP is carried out until an upper surface of the liner film 32 is exposed to remove the SOD film 33, and after that, a second interlayer insulating film 34 is formed so as to cover surfaces of the SOD film 33 and the liner film 32. As the second interlayer insulating film 34, for example, a silicon oxide film formed by plasma CVD can be used.

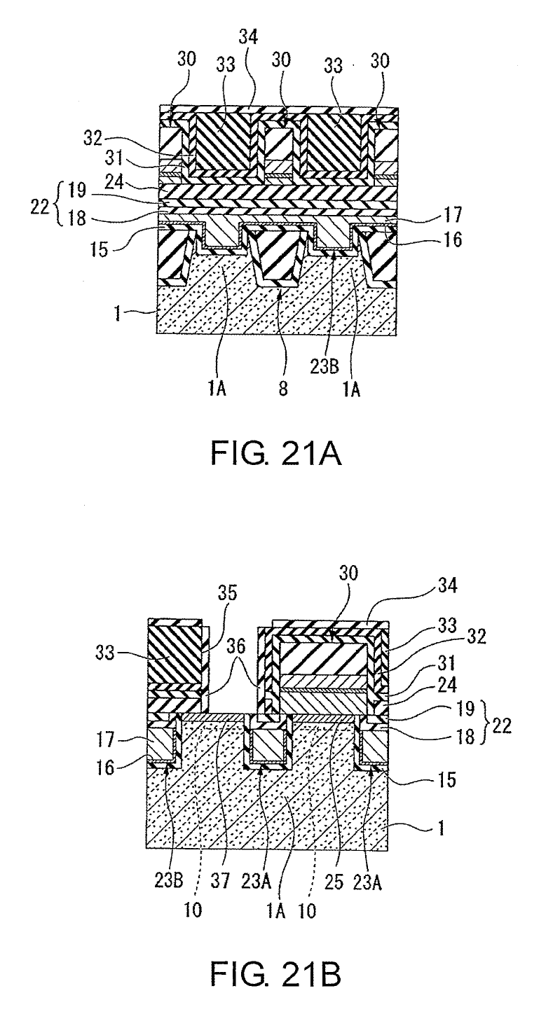

Next, as illustrated in FIG. 21A and FIG. 21B, a capacitor contact opening 35 is formed using photolithography and dry etching. The capacitor contact opening 35 is formed by self alignment contact (SAC) using the insulating film 31 and the liner film 32 formed on the side surfaces of the bit lines 30 as side walls. In this way, as illustrated in FIG. 21B, the surface of the silicon substrate 1 is exposed from the capacitor contact opening 35 at a portion at which the capacitor contact opening 35 and the active region 1A intersect with each other.

Next, a side wall (SW) insulating film 36 is formed by, after forming a silicon nitride film by, for example, thermal CVD, so as to cover an inner wall of the capacitor contact opening 35, carrying out etching back. Then, N-type impurities, for example, phosphorus, are ion implanted in the surface of the silicon substrate 1 which is exposed from the capacitor contact opening 35 with the second interlayer insulating film 34 being the mask to form the N-type impurity diffusion layer 37 in proximity to the surface of the silicon substrate 1.

The impurity diffusion layer 37 functions as a source/drain region of the transistor.

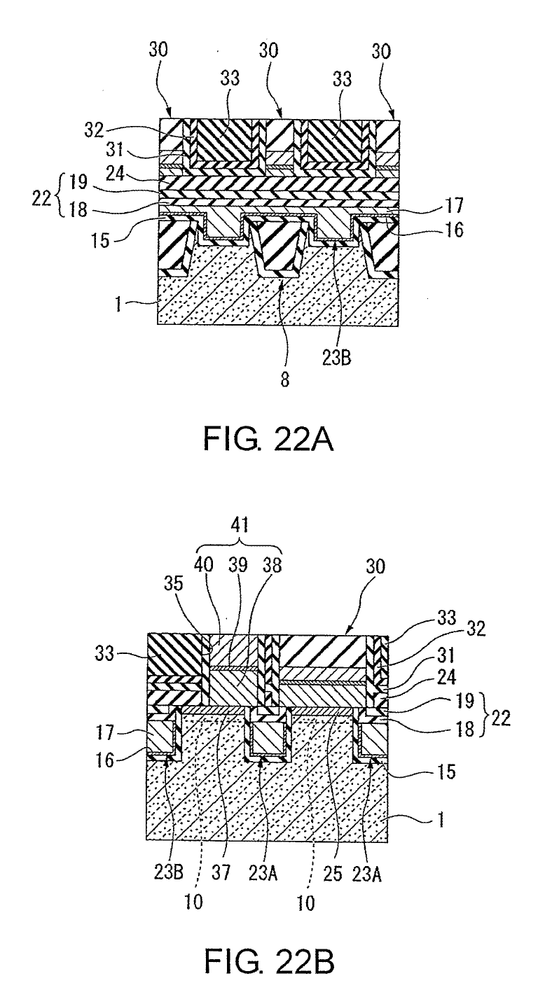

Next, as illustrated in FIG. 22A and FIG. 22B, a polysilicon film containing phosphorus is deposited by, for example, thermal CVD, so as to fill the contact opening 35. Then, etching back is carried out to leave the polysilicon film at the bottom of the capacitor contact opening 35 to form the conductive film 38. Then, a cobalt silicide (CoSi) film is formed on a surface of the conductive film 38 by sputtering to form the intervening layer 39, and after that, tungsten is deposited by, for example, CVD, so as to fill the capacitor contact opening 35 to form a tungsten film. Then, the tungsten film is removed by CMP until the surface of the SOD film 33 is exposed to leave the tungsten film only in the capacitor contact opening 35 to form the conductive film 40. In this way, as illustrated in FIG. 22B, the capacitor contact plug 41 including the stacked conductive film 38, intervening layer 39, and conductive film 40 is formed.

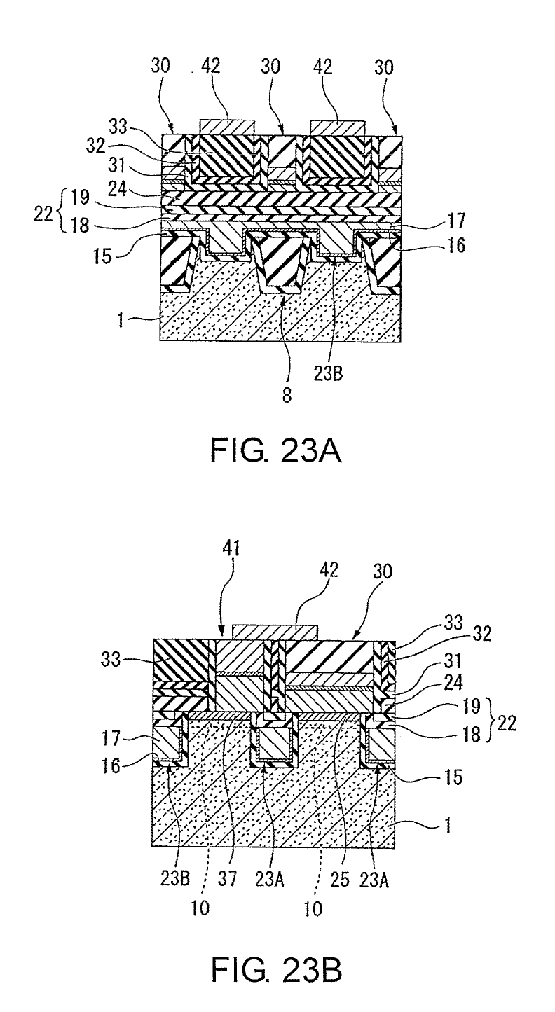

Next, as illustrated in FIG. 23A and FIG. 23B, a stacked film formed by depositing in sequence tungsten nitride (WN) and tungsten (W) is formed by, for example, sputtering, on the silicon substrate 1. By patterning the stacked film using photolithography and dry etching, the capacitor contact pad 42 is formed. In this case, the capacitor contact pad 42 is connected to the capacitor contact plug 41 at a portion at which a bottom surface of the capacitor contact pad 42 and an upper surface of the capacitor contact plug 41 overlap in plan view.

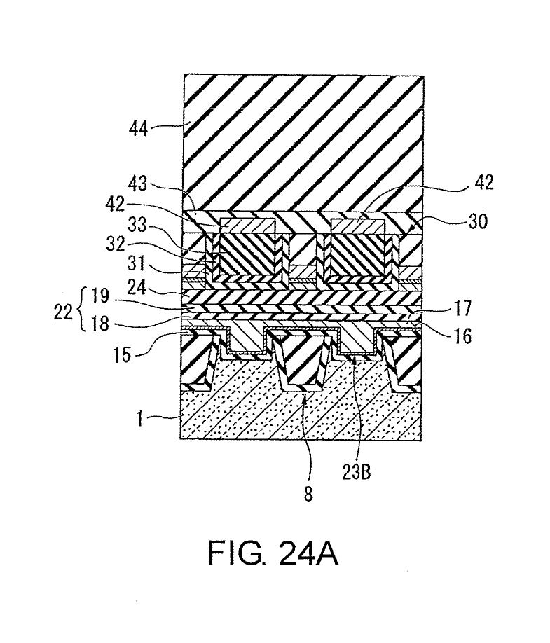

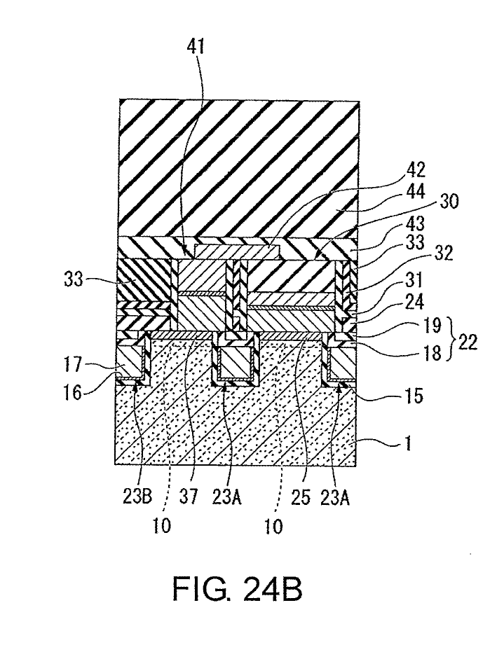

Next, as illustrated in FIG. 24A and FIG. 24B, a silicon nitride film is formed by, for example, thermal CVD, so as to cover the capacitor contact pad 42 to form the stopper film 43. Then, a silicon oxide film or the like is formed by, for example, plasma CVD, on the stopper film 43 to form the third interlayer insulating film 44.

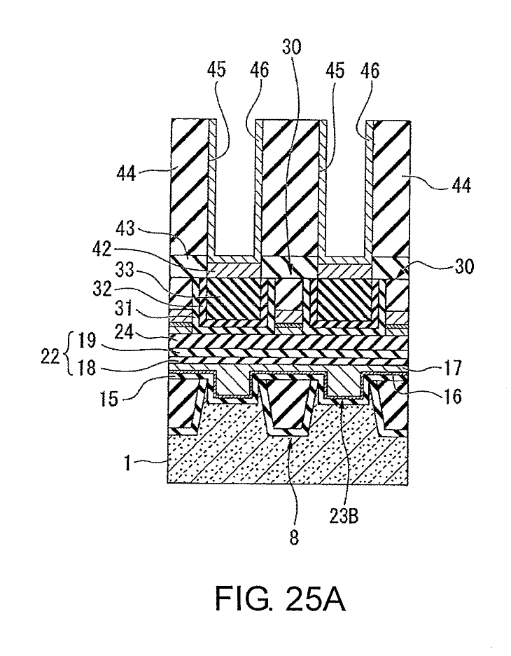

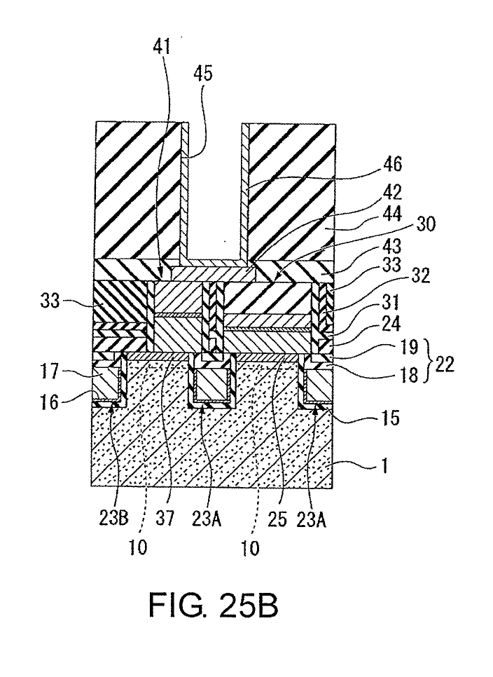

Next, as illustrated in FIG. 25A and FIG. 25B, cylinder holes 45 which pierce the third interlayer insulating film 44 and the stopper film 43 are formed using photolithography and dry etching so as to expose an upper surface of the capacitor contact pad 42. Then, the lower electrodes 46 of the capacitors are formed using titanium nitride or the like by, for example, CVD, so as to cover inner walls of the cylinder holes 45. A bottom portion of the lower electrode 46 is connected to the capacitor contact pad 42.

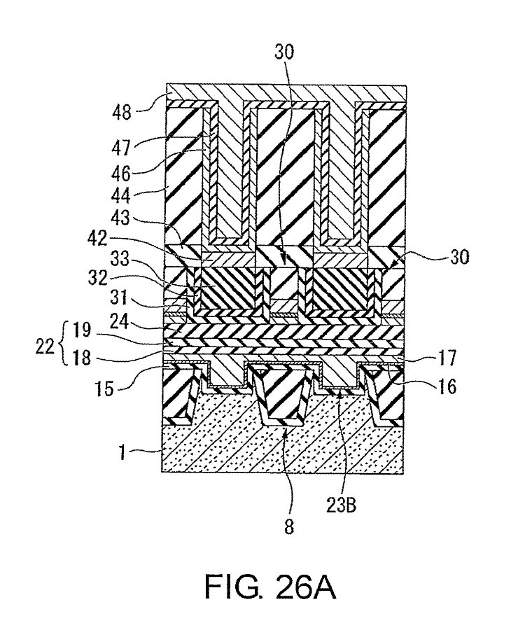

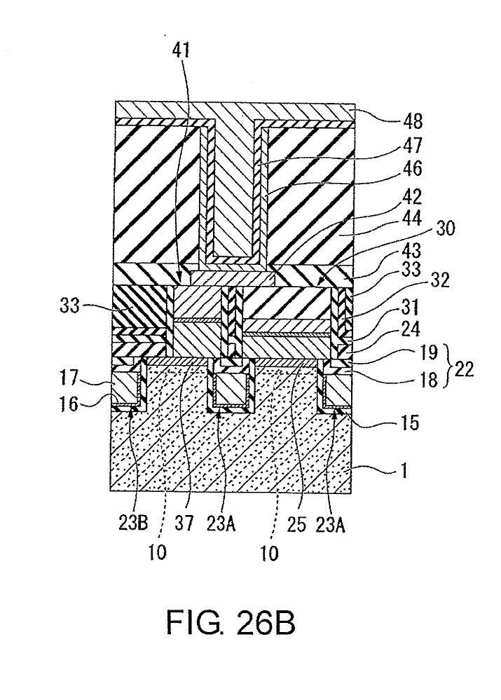

Next, as illustrated in FIG. 26A and FIG. 26B, the capacitor insulating film 47 is formed by, for example, ALD, so as to cover exposed surfaces of the third interlayer insulating film 44 and of the lower electrodes 46. As the capacitor insulating film 47, for example, zirconium oxide (ZrO₂), aluminum oxide (Al₂O₃), hafnium oxide (HfO₂), or a stacked film thereof can be used. Then, the upper electrode 48 of the capacitor elements is formed using titanium nitride or the like by, for example, CVD, so as to cover the surface of the capacitor insulating film 47. In this way, the capacitors are formed.

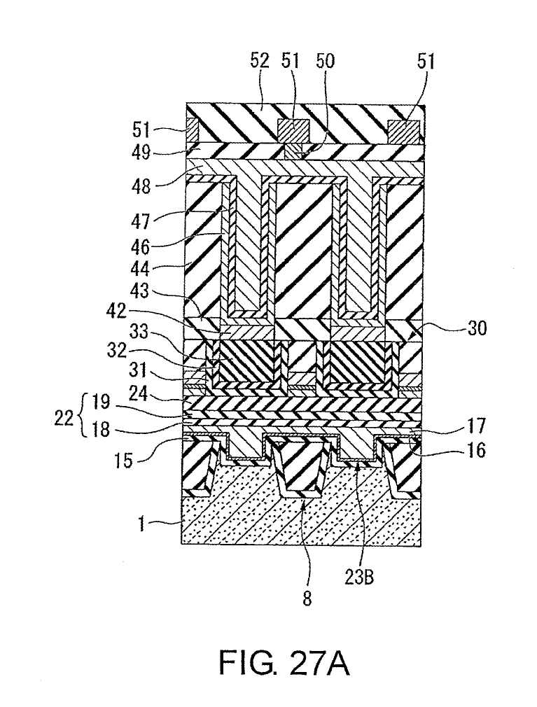

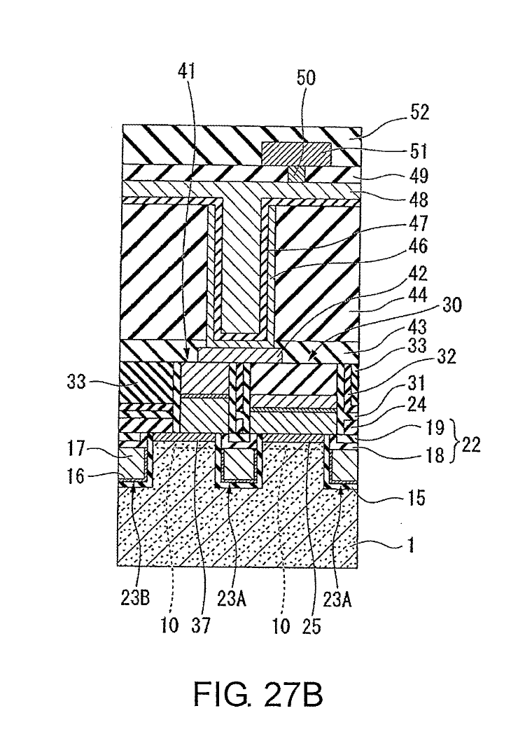

Next, as illustrated in FIG. 27A and FIG. 27B, an upper wiring layer is formed via the capacitor elements. First, the fourth interlayer insulating film 49 which is a silicon oxide film or the like is formed by, for example, plasma CVD, so as to cover the upper electrode 48. After that, a contact hole (not shown) is formed in the fourth interlayer insulating film 49 using photolithography and dry etching. Then, after filling the contact hole with tungsten or the like by, for example, CVD, tungsten or the like in excess on the fourth interlayer insulating film 49 is removed by CMP to form the contact plugs 50. Then, a film of aluminum (Al), copper (Cu), or the like is formed on the fourth interlayer insulating film 49, and then patterning is carried out to form the upper wiring 51. The upper wiring 51 is connected to the upper electrode 48 via the contact plug 50. After that, the protective film 52 is formed on the surface to complete the memory cells of the DRAM 100.

In this way, the DRAM 100 of this embodiment is manufactured.

As described above, according to the method of manufacturing the DRAM (semiconductor device) 100 of this embodiment, the intervening layer 16 which is a titanium nitride film containing carbon at a concentration of 3×10²⁰ to 7×10²⁰ atoms/cm³ (about 1% in content by percentage) is formed on the silicon substrate 1, and the conductive film 17 which is a tungsten film is formed on the intervening layer 16 using a tungsten hexafluoride gas and a diborane gas. The conductive film 17 is formed of tungsten having enlarged grain boundaries and a low resistance, and the intervening layer 16 is formed of a titanium nitride film with inhibited columnar crystallinity. Therefore, diffusion of boron (B) from the conductive film (tungsten film) 17 into the silicon substrate (semiconductor substrate) 1 can be prevented.

The technical scope of this invention is not limited to the embodiment described above, and various modifications thereof are possible within the gist of this invention. For example, in the DRAM 100 of the above-mentioned embodiment, recessed channel transistors are used as buried transistors in which word lines are completely buried in a semiconductor substrate in the structure of the memory cells, but this invention is not limited thereto, and various kinds of buried transistors including saddle fin transistors are applicable.

What is claimed is:

1. A semiconductor device, comprising:
a titanium nitride film comprising carbon, the titanium nitride film being formed over a semiconductor substrate; and
a tungsten film comprising boron, the tungsten film being formed over the titanium nitride film.

2. A semiconductor device according to claim 1, wherein the titanium nitride film is amorphous.

3. A semiconductor device according to claim 1, wherein the titanium nitride film has a carbon concentration of 3×10²⁰ atoms/cm³ or more and 7×10²⁰ atoms/cm³ or less.

4. A semiconductor device according to claim 1, wherein the titanium nitride film has a thickness of 3 nm or more and 5 nm or less.

5. A semiconductor device according to claim 1, wherein the tungsten film has a grain size of 80 nm or more and 120 nm or less.

6. A semiconductor device according to claim 1, further comprising an insulating film provided between the semiconductor substrate and the titanium nitride film.

7. A semiconductor device, comprising:
a gate groove provided in a semiconductor substrate;
an insulating film provided so as to cover a surface of the gate groove;
a titanium nitride film comprising carbon, the titanium nitride film being provided over the insulating film; and
a tungsten film provided over the titanium nitride film.

8. A semiconductor device according to claim 7, wherein the titanium nitride film is amorphous.

9. A semiconductor device according to claim 7, wherein the titanium nitride film has a carbon concentration of 3×10²⁰ atoms/cm³ or more and 7×10²⁰ atoms/cm³ or less.

10. A semiconductor device according to claim 9, wherein the titanium nitride film has a thickness of 3 nm or more and 5 nm or less.

11. A semiconductor device according to claim 7, wherein the tungsten film comprises boron.

12. A semiconductor device according to claim 11, wherein the tungsten film has a grain size of 80 nm or more and 120 nm or less.

13. A semiconductor device according to claim 7, wherein the insulating film comprises a gate insulating film comprising a silicon oxide film.

14. A semiconductor device according to claim 13, wherein the titanium nitride film and the tungsten film form a word line.

15. A semiconductor device according to claim 14, further comprising diffusion layers provided in portions of the semiconductor substrate on both sides of the gate groove.

16. A semiconductor device, comprising:
an element isolation region provided in a semiconductor substrate and defining an active region;
a groove provided in a surface layer of the semiconductor substrate, the groove extending in a first direction intersecting with the element isolation region and the active region;
a gate insulating film covering a surface of the groove for a gate electrode;
a buried gate electrode formed so as to be buried at a bottom portion of the groove, the buried gate electrode being formed as a word line; and
a pair of diffusion layers that is provided on an upper surface of the semiconductor substrate, and is located on both sides of the groove for a gate electrode in the active region,
wherein the buried gate electrode comprises a titanium nitride film and a tungsten film, the titanium nitride film being provided on the gate insulating film and comprising carbon, the tungsten film being provided on the titanium nitride film.

17. A semiconductor device according to claim 16, wherein the titanium nitride film is amorphous, and has a carbon concentration of 3×10²⁰ atoms/cm³ or more and 7×10²⁰ atoms/cm³ or less.

18. A semiconductor device according to claim 16, wherein the tungsten film comprises boron.

19. A semiconductor device according to claim 16, further comprising a bit line electrically connected to one diffusion layer of the pair of diffusion layers and extending in a second direction intersecting with the first direction.

20. A semiconductor device according to claim 19, further comprising:
an interlayer insulating film provided so as to cover the bit line;
a contact plug electrically connected to another diffusion layer of the pair of diffusion layers and provided in the interlayer insulating film; and
a capacitor electrically connected to the contact plug.
